(19) United States
(12) Patent Application Publication
(10) Pub. No.: US 2026/0362643 A1
(43) Pub. Date: Nov. 12, 2026

(54) THERMAL MANAGEMENT USING ELECTRICALLY CONDUCTING FLUIDS

(71) Applicant: Molten Dynamics Inc., Austin, TX (US)

(72) Inventors: Andrew Miner, Austin, TX (US); Uttam Ghoshal, Austin, TX (US); Key Kolle, Luling, TX (US)

(21) Appl. No.: 19/662,156

(22) Filed: Apr. 29, 2026

Related U.S. Application Data
(60) Provisional application No. 63/834,984, filed on May 9, 2025.

(51) Int. Cl. H05K 7/20

(52) U.S. Cl. CPC H05K 7/20272; H05K 7/20263; H05K 7/20281

(57) ABSTRACT

A thermal management apparatus for high-power density devices is disclosed, featuring a dual-loop architecture to enhance heat dissipation. The system includes a heat spreader thermally coupled to the device, a primary fluid circuit sealed within the heat spreader containing an electrically conducting fluid, such as a gallium-based liquid metal alloy, and a secondary fluid circuit fluidly isolated from the primary circuit containing a non-metallic coolant, such as water. Heat is absorbed by the primary circuit, transferred to the secondary circuit via a heat exchange wall, and rejected through a heat rejection element. The primary circuit employs advanced pumping mechanisms, including magnetohydrodynamic pumps or magnetically coupled impellers, to circulate the liquid metal without mechanical penetrations or electrical feedthroughs. The system enables efficient heat spreading, reduced thermal resistance, and dynamic control of fluid flow based on temperature or operating conditions. Applications include high-performance computing, data centers, and electronics requiring reliable thermal management.

### CROSS-REFERENCE TO RELATED APPLICATIONS

This application claims priority to U.S. Provisional Patent Application Ser. No. 63/834,984, filed May 9, 2025, entitled HEAT SPREADING AND THERMAL MANAGEMENT USING ELECTRICALLY CONDUCTING FLUIDS.

### FIELD OF INVENTION

The present disclosure relates to the field of thermal management systems, specifically to cooling high-power density electronic devices using electrically conducting fluids and advanced pumping mechanisms.

### BACKGROUND

The increasing power and integration density of modern electronic devices has created significant challenges for thermal management. High-performance processors, graphics modules, and power electronics generate substantial heat during operation, requiring efficient cooling to maintain performance and prevent device failure. Traditional cooling methods, such as solid metal heat spreaders and finned heat sinks, are limited by material properties and often result in uneven temperature distribution and hotspots. Vapor chambers offer improved heat spreading but are constrained by nucleation limits and complex packaging.

Liquid cooling systems have been introduced to address these limitations, providing greater heat removal capacity than air-cooled solutions. However, common coolants like water have relatively low thermal conductivity, and mechanical pumps can add complexity, noise, and reliability concerns. Sealed-loop designs are needed to ensure robust operation and minimize maintenance, but achieving uniform and efficient cooling remains a challenge. There is a need for advanced thermal management systems that utilize high-conductivity fluids and innovative pumping mechanisms to deliver reliable and effective cooling for high-power electronic devices.

### SUMMARY

In one embodiment, the disclosure provides a thermal management apparatus comprising a heat spreader configured to be in thermal communication with a high-power density device, a primary fluid circuit disposed within the heat spreader and containing an electrically conducting fluid arranged to circulate to absorb and distribute heat from the high-power density device, a secondary fluid circuit fluidly isolated from and thermally coupled to the primary fluid circuit and containing a fluid different from the electrically conducting fluid, and a heat rejection element in thermal communication with the secondary fluid circuit, wherein the secondary fluid circuit is configured to receive heat from the primary fluid circuit and reject the heat at the heat rejection element to effect enhanced heat removal from the high-power density device.

In addition to one or more of the features described herein, the fluid of the secondary fluid circuit comprises water.

In addition to one or more of the features described herein, the primary fluid circuit is fully sealed within the heat spreader.

In addition to one or more of the features described herein, the apparatus further comprises a pump in the primary fluid circuit, the pump being a magnetohydrodynamic pump configured to drive circulation of the electrically conducting fluid.

In addition to one or more of the features described herein, the apparatus further comprises a pump in the primary fluid circuit, the pump comprising a mechanically driven pump configured to drive circulation of the electrically conducting fluid through the primary fluid circuit, wherein the mechanically driven pump comprises an impeller pump, a centrifugal pump, an axial-flow pump, a mixed-flow pump, a positive-displacement pump, or another mechanically driven pump suitable for use with the electrically conducting fluid.

In addition to one or more of the features described herein, the magnetohydrodynamic pump comprises a Halbach array of permanent magnets arranged to concentrate magnetic flux within a section of the primary fluid circuit while reducing stray magnetic fields external to the section.

In addition to one or more of the features described herein, the thermal management apparatus comprises a magnetohydrodynamic pump including a Halbach array having a first opposing portion disposed on a first side of a primary fluid circuit and electrically coupled as a negative electrode, a second opposing portion disposed on a second side of the main fluid circuit opposite the first side and electrically coupled as a positive electrode, and an insulator disposed between the first opposing portion and the second opposing portion, wherein electrical current passes between the first opposing portion and the second opposing portion through the electrically conducting fluid in the main fluid circuit to generate pumping of the electrically conducting fluid.

In addition to one or more of the features described herein, the primary fluid circuit is driven by an impeller magnetically coupled to a driver located in the heat spreader.

In addition to one or more of the features described herein, the driver is disposed in the heat spreader and comprises a flow-driven rotor hydraulically coupled to the secondary fluid circuit such that flow of the fluid in the secondary fluid circuit rotates the driver.

In addition to one or more of the features described herein, the driver is disposed in the heat spreader and comprises an electrically driven motor configured to rotate the driver independently of fluid flow in the secondary fluid circuit.

In addition to one or more of the features described herein, the apparatus further comprises a controller configured to modulate a circulation rate in at least one of the primary fluid circuit or the secondary fluid circuit in response to a temperature of the high-power density device.

In addition to one or more of the features described herein, the primary fluid circuit comprises a plurality of flow channels disposed in the heat spreader and arranged to circulate the electrically conducting fluid proximate the high-power density device.

In addition to one or more of the features described herein, the apparatus further comprises a respective pump hydraulically coupled to each of the plurality of flow channels to drive flow of the electrically conducting fluid through the respective flow channel.

In addition to one or more of the features described herein, the respective pumps are individually controllable such that, during operation, a first pump of the respective pumps drives flow in a first direction at a first flow rate in a first flow channel while a second pump of the respective pumps drives flow in a second direction, opposite the first direction, at a second flow rate in a second flow channel.

In addition to one or more of the features described herein, the apparatus further comprises a control system including a controller and a plurality of temperature sensors positioned to sense temperature at respective locations of at least one of the high-power density device and the heat spreader, wherein the controller is configured to control at least one of speed or direction of at least a subset of the respective pumps based on temperature sensor data from the plurality of temperature sensors.

In addition to one or more of the features described herein, the controller is further configured to control at least one of speed or direction of at least a subset of the respective pumps based on an operating mode of the high-power density device.

In addition to one or more of the features described herein, the operating mode comprises at least one of a power state, a workload level, a clock frequency, a voltage setting, a thermal design power limit, or a throttling state of the high-power density device.

In addition to one or more of the features described herein, the controller is configured to determine a temperature gradient across at least a portion of the heat spreader based on the temperature sensor data and to control at least one of speed or direction of the respective pumps to produce a non-uniform flow distribution among the plurality of flow channels that reduces the temperature gradient.

In one embodiment, the disclosure provides a thermal management apparatus comprising a heat spreader configured to be mounted in thermal communication with a high-power density device, a primary fluid circuit fully sealed within the heat spreader and containing a liquid metal arranged to circulate within the heat spreader to absorb heat from a region adjacent the high-power density device, a secondary fluid circuit fluidly isolated from the primary fluid circuit and containing a non-metallic coolant, the secondary fluid circuit being thermally coupled to the primary fluid circuit through a heat exchange wall within the heat spreader, and a magnetically coupled pump comprising an internal impeller disposed in the primary fluid circuit and a flow-driven driver disposed in the heat spreader and hydraulically coupled to the secondary fluid circuit, wherein flow of the non-metallic coolant in the secondary fluid circuit rotates the flow-driven driver, the flow-driven driver magnetically rotates the internal impeller through a sealed wall, and rotation of the internal impeller circulates the liquid metal in the primary fluid circuit while the primary fluid circuit remains fully sealed without a mechanical shaft penetration and without an electrical feedthrough into the primary fluid circuit.

In one embodiment, the disclosure provides a thermal management apparatus comprising a heat spreader configured to be mounted in thermal communication with a high-power density device, a primary fluid circuit fully sealed within the heat spreader and containing a liquid metal arranged to circulate within the heat spreader to absorb heat from a region adjacent the high-power density device, a secondary fluid circuit fluidly isolated from the primary fluid circuit and containing a non-metallic coolant, the secondary fluid circuit being thermally coupled to the primary fluid circuit through a heat exchange wall within the heat spreader, a heat rejection element in thermal communication with the secondary fluid circuit, and a magnetically coupled pump comprising an internal impeller disposed in the primary fluid circuit and an electrically driven motor disposed in the heat spreader, the electrically driven motor being configured to magnetically rotate the internal impeller through a sealed wall, wherein rotation of the internal impeller circulates the liquid metal in the primary fluid circuit while the primary fluid circuit remains fully sealed without a mechanical shaft penetration and without an electrical feedthrough into the primary fluid circuit.

Additional technical features and benefits are realized through the techniques of the present disclosure. Embodiments and aspects of the disclosure are described in detail herein and are considered a part of the claimed subject matter. For a better understanding, refer to the detailed description and to the drawings.

### BRIEF DESCRIPTION OF DRAWINGS

FIG. 1A is a perspective view of a thermal management apparatus having a heat spreader, a heat rejection element, and a high-power density device in accordance with an embodiment.

FIG. 1B is a side view of a thermal management apparatus having a heat spreader, a heat rejection element, and a high-power density device in accordance with an embodiment.

FIG. 1C is a cross-sectional view of a thermal management apparatus having a heat spreader, a heat rejection element, and a high-power density device in accordance with an embodiment.

FIG. 2 is a cross-sectional view of a thermal management apparatus illustrating a cooling system with a dual-loop architecture for thermal management of a high-power density device in accordance with an embodiment.

FIG. 3 is a cross-sectional view of a thermal management apparatus with a primary fluid circuit driven by a magnetically coupled impeller and an electrically driven motor in accordance with an embodiment.

FIG. 4 is a block diagram illustrating a thermal management system for controlling heat dissipation in a high-power density device in accordance with an embodiment.

FIG. 5A is a perspective view of a magnetohydrodynamic pump system with a cylindrical conduit for circulating electrically conducting fluid in accordance with an embodiment.

FIG. 5B is a cross-sectional view of a magnetohydrodynamic pump, showing the interaction of magnetic flux, electrical current, and resulting Lorentz force within an electrically conducting fluid in accordance with an embodiment.

In the accompanying figures and following detailed description of the disclosed embodiments, the various elements illustrated in the figures are provided.

### DETAILED DESCRIPTION

The following detailed description provides an in-depth explanation of the described technology, its embodiments, and its applications. The described technology pertains to the field of thermal management systems, particularly those designed to efficiently dissipate heat from high-power density devices using electrically conducting fluids and advanced pumping mechanisms. While specific embodiments and examples are described herein to illustrate the principles of the described technology, these are provided for explanatory purposes and are not to be construed as limiting the scope of the described technology.

Those skilled in the art will understand that certain widely recognized methods, components, and processes may not be described in detail to maintain clarity and simplicity. Furthermore, the described subject matter allows for various modifications, rearrangements, and alternative configurations that achieve the same or similar objectives as those disclosed herein. Such variations are intended to fall within the spirit and scope of the subject matter as defined by the appended claims.

The challenge of achieving effective thermal management in high-power density devices (HPDDs) has become increasingly significant due to the growing computational demands and integration density of modern electronics, such as processors, GPUs, and AI engines. Conventional cooling methods, including finned heat sinks, solid metal heat spreaders, and vapor chambers, face certain limitations. Finned heat sinks, while increasing the effective surface area for heat dissipation, often exhibit uneven temperature distribution due to the thermal resistance of the base material. Vapor chambers, which rely on phase change mechanisms, are constrained by nucleation limits and interface resistances, reducing their efficiency in high heat flux scenarios. Liquid cooling systems, though capable of higher heat removal rates, typically use fluids like water with low thermal conductivity, and their reliance on mechanical pumps introduces noise, reliability concerns, and increased system complexity. These limitations result in hotspots, uneven cooling, and suboptimal performance, particularly in applications requiring sustained operation under high thermal loads.

The present system addresses these challenges by introducing a novel thermal management approach that utilizes electrically conducting fluids, such as liquid metal alloys, in combination with advanced pumping mechanisms. Exemplary embodiments employ a dual-loop architecture, where a primary fluid circuit containing a high-conductivity liquid metal is positioned near the HPDD to absorb and distribute heat efficiently. This primary loop is thermally coupled to a secondary fluid circuit containing a lower-cost coolant, such as water, which facilitates heat rejection to the ambient environment or a remote cooling system. The use of magnetohydrodynamic (MHD) pumps or magnetically coupled impellers eliminates the need for mechanical penetrations or electrical feedthroughs, ensuring a fully sealed system that enhances reliability and reduces contamination risks. Additionally, the integration of Halbach magnet arrays in the MHD pumps optimizes magnetic flux density within the fluid channels, improving pump efficiency and enabling silent operation.

By utilizing the advanced thermophysical properties of liquid metals and novel pumping technologies, the described system achieves consistent heat distribution, reduces thermal resistance, and facilitates fluid flow that is independent of gravity. The system design enables modular control of fluid circulation rates and directions, allowing for dynamic adjustments based on temperature profiles or operating modes of the HPDD. This methodology improves cooling performance while also decreasing energy consumption and operational noise, making the system well-suited for high-performance computing environments, data centers, and AI engine applications.

In many thermal management applications for high-power density devices, the selection of a coolant involves balancing heat transfer performance, reliability, materials compatibility, and cost. Traditional liquid coolants used in electronics cooling typically include water, water-glycol mixtures, dielectric fluids (e.g., engineered fluorinated liquids or hydrocarbon-based dielectric coolants), and various synthetic heat transfer oils. While these conventional fluids can provide effective bulk heat transport when circulated through cold plates or heat exchangers, they are generally limited in thermal performance near localized heat sources by relatively low thermal conductivity and, in certain cases, by constraints associated with electrical conductivity, corrosion, and allowable operating temperature range.

Electrically conducting fluids, including liquid metals and liquid metal alloys, exhibit thermophysical properties that differ substantially from those of conventional coolants. In particular, liquid metals typically have thermal conductivities that are one to two orders of magnitude greater than many conventional liquids. This higher thermal conductivity enables rapid lateral heat spreading within the liquid phase and reduces local thermal gradients within flow passages proximate a heat input region. Stated differently, for a given geometry and flow condition, a liquid metal circulating in a channel adjacent a heat source can transport absorbed heat along the channel more efficiently by conduction within the fluid itself, and can therefore reduce hotspot formation and improve temperature uniformity across a heat spreader.

In some embodiments, the electrically conducting fluid comprises a gallium-containing liquid metal or liquid metal alloy. Examples of suitable gallium-containing liquids include gallium-indium alloys and gallium-indium-tin alloys, including eutectic or near-eutectic formulations that are liquid at or near room temperature. In certain implementations, the gallium-containing liquid metal alloy comprises Ga—In—Sn, such as an alloy having gallium as a majority component by weight with indium and tin as additional components. Gallium-containing liquid metal alloys can provide high thermal conductivity and electrical conductivity while remaining flowable in operating temperature ranges typical of electronics cooling.

Liquid metals can also exhibit favorable combinations of density, viscosity, and thermal diffusivity that enable effective convective heat transfer. In some configurations, the improved thermal transport within the fluid reduces the sensitivity of overall thermal resistance to local stagnation zones or uneven wetting, thereby enabling a circulating liquid metal to function as an active heat spreading medium. Further, because a liquid metal is electrically conducting, certain pumping technologies can be employed that are not practicable with dielectric or weakly conducting liquids, including magnetohydrodynamic and other electromagnetic pumping approaches that can be implemented without mechanical penetrations into a sealed fluid circuit.

Despite these performance advantages, liquid metals and liquid metal alloys can be significantly more expensive than conventional coolants such as water. Liquid metals may also impose additional design considerations related to containment, compatibility with structural materials, and long-term stability. Accordingly, systems described herein can be configured to exploit the superior local thermal performance of a liquid metal while limiting the quantity of liquid metal used, thereby managing overall system cost.

In exemplary implementations, a thermal management apparatus includes a dual-loop architecture comprising a primary fluid circuit and a secondary fluid circuit that are thermally coupled but fluidly isolated. The primary fluid circuit is disposed within, or otherwise integrated with, a heat spreader proximate the high-power density device. The primary fluid circuit contains a liquid metal or liquid metal alloy and is sized to occupy a relatively small volume localized near the heat source. This arrangement can concentrate use of the liquid metal in the region where high thermal conductivity provides the greatest benefit, namely, near the heat input region where heat flux is highest and temperature non-uniformity is most likely to occur.

The secondary fluid circuit contains a different coolant, such as water, a water-glycol mixture, or a dielectric coolant, and is thermally coupled to the primary circuit through a heat exchange wall or other heat exchange region within the heat spreader. The secondary fluid circuit may include a comparatively larger volume of coolant and may extend to a remote heat rejection element, such as a radiator, cold plate, facility water interface, or other heat exchanger. Because the secondary circuit is generally responsible for transporting heat over longer distances and rejecting heat to ambient or to a facility cooling resource, it can be economically advantageous to use a lower-cost coolant in the secondary circuit. For example, water may provide high volumetric heat capacity and low cost for bulk heat transport, even though its thermal conductivity is substantially lower than that of liquid metals.

In operation, heat generated by the high-power density device is transferred into the heat spreader and absorbed by the liquid metal in the primary fluid circuit. Circulation of the liquid metal distributes the absorbed heat along the primary circuit and conveys the heat to the heat exchange region. At the heat exchange region, heat is transferred from the liquid metal across a thermally conductive wall into the secondary coolant, which then carries the heat away for rejection. By limiting the liquid metal to a localized primary circuit while using a lower-cost coolant in the secondary circuit, the thermal management apparatus can achieve enhanced heat removal and improved temperature uniformity near the heat source while controlling material costs associated with the use of liquid metal.

In some embodiments, the primary liquid metal circuit is operated at a higher circulation rate than the secondary circuit to provide strong local heat spreading and to reduce thermal resistance at the heat input region. Meanwhile, the secondary circuit may be operated at a circulation rate selected to optimize bulk transport and heat rejection efficiency, including accommodating system-level constraints such as allowable pressure drop, pump power, and available heat exchanger area. The ability to independently select coolants and circulation conditions for the two circuits enables system-level optimization in which the primary circuit delivers high local heat transfer performance and the secondary circuit delivers cost-effective heat transport and heat rejection. In this manner, the combination of a small-volume liquid metal primary circuit and a larger-volume conventional coolant secondary circuit can maximize heat removal performance while controlling overall cost and enabling use of conventional external plumbing and heat rejection infrastructure.

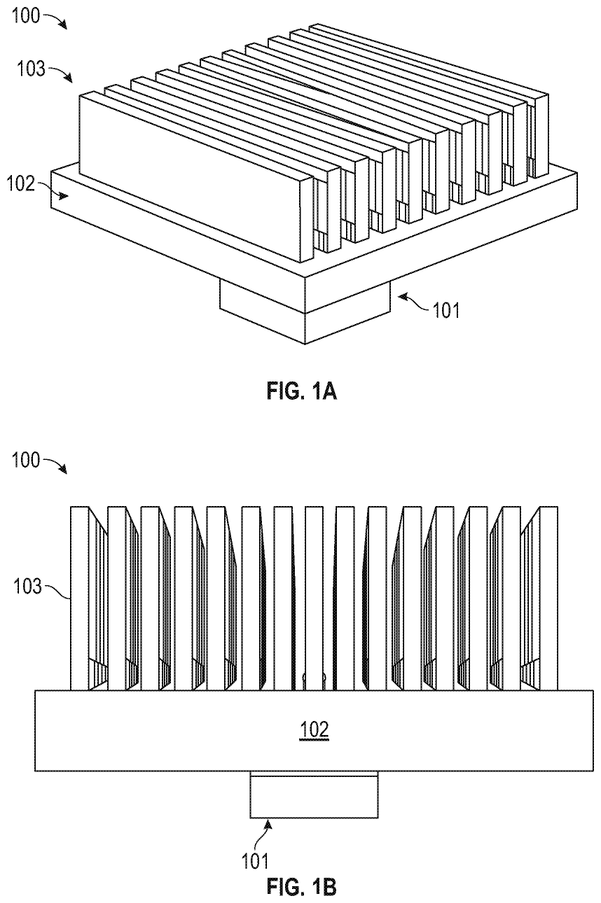

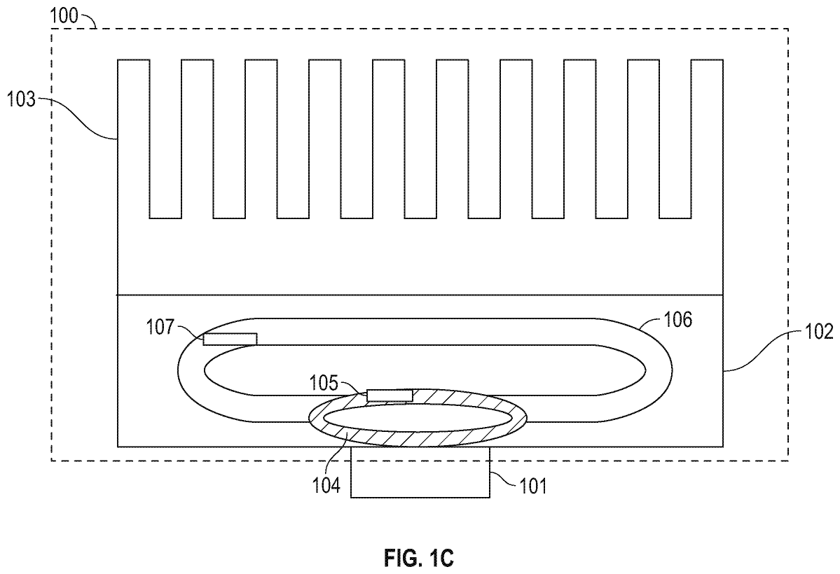

FIG. 1A-1C illustrate an example thermal management apparatus 100 configured to remove heat generated by a high-power density device 101. The high-power density device 101 may include, for example, a processor, graphics processor, accelerator, power semiconductor module, laser diode, light-emitting diode module, memory module, or other electronic device that produces localized heat flux during operation.

As shown in FIGS. 1A and 1B, the thermal management apparatus 100 includes a heat spreader 102 disposed in thermal communication with the high-power density device 101. In operation, heat generated by the high-power density device 101 is conducted into the heat spreader 102, which functions to receive and distribute the heat over a larger effective area. The heat spreader 102 may include a thermally conductive body (e.g., copper, aluminum, composites, or other thermally conductive materials) configured to contact the high-power density device 101 directly or through an intermediate thermal interface material layer.

The thermal management apparatus 100 further includes a heat rejection element 103 configured to reject heat away from the heat spreader 102 to an external environment or a remote cooling resource. In the illustrated example of FIGS. 1A and 1B, the heat rejection element 103 is depicted as a finned structure, such as a heat sink, radiator, or other heat exchanger suitable to transfer heat to air. In other embodiments, the heat rejection element 103 may comprise a liquid-to-liquid heat exchanger, a cold plate coupled to facility water, a remote radiator, or any other structure configured to remove heat from a coolant.

FIG. 1C schematically illustrates an embodiment in which the heat spreader 102 includes at least two thermally coupled but fluidly isolated coolant circuits. A primary fluid circuit 104 is disposed within, or otherwise integrated with, the heat spreader 102 to circulate a coolant proximate the region of the heat spreader 102 adjacent the high-power density device 101. In some embodiments, the primary fluid circuit 104 contains an electrically conducting fluid, such as a liquid metal or liquid metal alloy, selected to provide relatively high thermal conductivity and enhanced heat spreading performance in the vicinity of the high-power density device 101. During operation, the electrically conducting fluid circulating in the primary fluid circuit 104 absorbs heat from a region adjacent the high-power density device 101 and transports and distributes the absorbed heat along the primary fluid circuit 104, thereby reducing localized hotspots and improving temperature uniformity across the heat spreader 102.

In some embodiments, the heat spreader includes one or more heat-transfer enhancement features disposed in a region of the primary fluid circuit adjacent the high-power density device. For example, the heat spreader may include a plurality of protrusions, pins, fins, posts, ribs, dimples, textured wall features, porous structures, or combinations thereof that extend into a flow passage of the primary fluid circuit to increase an effective heat transfer area and/or to promote local mixing and turbulence of the electrically conducting fluid. In certain implementations, the enhancement features are localized to a hot-spot region corresponding to the high-power density device to reduce thermal resistance at the heat input region while limiting pressure drop in downstream portions of the primary fluid circuit. The enhancement features may be formed integrally with the heat spreader body or may comprise inserts coupled to the heat spreader body by soldering, brazing, diffusion bonding, adhesive bonding, mechanical retention, or combinations thereof, and the enhancement features may comprise a metal, a ceramic, a carbon-based material, or a composite material selected for thermal conductivity and compatibility with the electrically conducting fluid.

A primary fluid pump 105 is provided to drive circulation of the electrically conducting fluid in the primary fluid circuit 104. The primary fluid pump 105 may be disposed in-line with the primary fluid circuit 104 and may be integrated into the heat spreader 102 such that the primary fluid circuit 104 is fully sealed. In such embodiments, the electrically conducting fluid may be contained within the heat spreader 102 without requiring external plumbing connections or routine service access to the primary fluid circuit 104, thereby reducing leakage risk and contamination risk. The primary fluid pump 105 may comprise an electromagnetic pump, a magnetohydrodynamic pump, a magnetically coupled impeller pump, or another pumping mechanism compatible with electrically conducting fluids.

In some embodiments, the primary fluid pump 105 may comprise a conventional mechanical pump configured to circulate the electrically conducting fluid through the primary fluid circuit 104. For example, the primary fluid pump 105 may comprise an impeller pump, a centrifugal pump, an axial-flow pump, a mixed-flow pump, a positive-displacement pump, or another mechanically driven pump suitable for use with the electrically conducting fluid. In such implementations, the primary fluid pump 105 may be integrated into the heat spreader 102 or may be fluidly coupled to the primary fluid circuit 104 as a separate pump unit, and mechanical power may be provided by an electric motor through a shaft, coupling, gear train, or other drive mechanism. In some implementations, the mechanically driven pump may be used in place of, or in combination with, a magnetohydrodynamic pump, an electromagnetic pump, or a magnetically coupled impeller pump, depending on target flow rate, pressure rise, packaging constraints, reliability requirements, and cost considerations.

In some embodiments, a first fluid pump 105 comprises a mechanically driven pump configured to circulate the electrically conducting fluid through a first fluid circuit 104. For example, the first fluid pump 105 may comprise a centrifugal impeller pump having an impeller disposed within a pump housing fluidly coupled to the first fluid circuit 104, wherein rotation of the impeller draws the electrically conducting fluid into the pump housing and discharges the electrically conducting fluid at an elevated pressure to drive circulation through one or more flow channels of the first fluid circuit 104. The centrifugal impeller pump may be driven by an electric motor and may be selected and configured to provide a target flow rate and pressure rise for the electrically conducting fluid based on a geometry of the first fluid circuit 104, a viscosity and density of the electrically conducting fluid, and a heat load associated with the high-power density device 101.

In some embodiments, circulation of the electrically conducting fluid is provided by a magnetically coupled impeller or by an induction-type electromagnetic pump such that the primary fluid circuit remains fully sealed without a mechanical shaft penetration and without an electrical feedthrough into the primary fluid circuit. In other embodiments, circulation of the electrically conducting fluid is provided by a direct-current magnetohydrodynamic pump that establishes electrical current through the electrically conducting fluid using electrodes associated with the primary fluid circuit. In such electrode-based embodiments, one or more electrical connections may be provided to the electrodes while the primary fluid circuit remains sealed against coolant leakage, and the electrode structures and associated insulation may be configured to maintain electrical isolation and corrosion resistance while enabling the applied current to generate a Lorentz-force pumping action.

The heat spreader 102 further includes a secondary fluid circuit 106 that is fluidly isolated from the primary fluid circuit 104 and contains a coolant different from the electrically conducting fluid. For example, the secondary fluid circuit 106 may contain water, a water-glycol mixture, a dielectric coolant, or another non-metallic coolant. The secondary fluid circuit 106 is thermally coupled to the primary fluid circuit 104 such that heat extracted and transported by the electrically conducting fluid in the primary fluid circuit 104 is transferred across an intervening wall or heat exchange region within the heat spreader 102 into the coolant of the secondary fluid circuit 106. The secondary fluid circuit 106 thereby receives heat from the primary fluid circuit 104 while remaining fluidly isolated from the electrically conducting fluid, which can reduce cost and simplify external plumbing by enabling use of conventional secondary coolants.

A secondary fluid pump 107 is provided to circulate coolant through the secondary fluid circuit 106. In the illustrated example, the secondary fluid circuit 106 is thermally coupled to the heat rejection element 103 such that heat carried by the coolant in the secondary fluid circuit 106 is rejected at the heat rejection element 103. For instance, the secondary fluid circuit 106 may pass through, or be coupled to, a heat exchanger region within the heat rejection element 103, enabling transfer of heat from the secondary coolant to ambient air or to another cooling medium. Accordingly, the combination of the primary fluid circuit 104 and the secondary fluid circuit 106 provides a dual-loop thermal management architecture in which a high-conductivity electrically conducting fluid is used locally near the high-power density device 101 for efficient heat absorption and spreading, while a different coolant in the secondary circuit 106 is used for heat transport and rejection at the heat rejection element 103.

In some embodiments, the secondary fluid circuit 106 is configured to transport heat over a distance greater than a characteristic dimension of the heat spreader 102, such that the secondary fluid circuit 106 extends away from the heat spreader 102 through one or more tubes, pipes, hoses, manifolds, or other conduits to a remote heat rejection element 103. For example, the secondary fluid circuit 106 may route coolant across a server chassis, to a chassis-level or board-level heat exchanger, to a rack-level coolant distribution unit, to a facility water interface, to a cooling tower, or to another remote cooling resource. In such implementations, the primary fluid circuit 104 may remain localized within or immediately adjacent the heat spreader 102 to provide high-performance heat absorption and spreading near the high-power density device 101, while the secondary fluid circuit 106 provides longer-distance transport of the extracted heat using external plumbing and a lower-cost coolant suitable for system-level heat rejection infrastructure.

Although FIG. 1C depicts the primary fluid circuit 104 and secondary fluid circuit 106 as single-loop flow paths, either circuit may include multiple channels, manifolds, heat exchange regions, or other flow features. Further, the heat rejection element 103 may be positioned directly on the heat spreader 102 as shown, or may be remote from the heat spreader 102 and coupled by the secondary fluid circuit 106. The depicted arrangement is therefore provided as an illustrative example of a thermal management apparatus 100 that uses a heat spreader 102 with a primary circuit containing an electrically conducting fluid and a thermally coupled secondary circuit containing a different coolant to provide enhanced heat removal from a high-power density device 101.

In various embodiments, the primary fluid circuit may be implemented using different channel and loop geometries depending on a desired heat spreading profile, allowable pressure drop, and packaging constraints. In some implementations, the primary fluid circuit comprises a plurality of interleaved channels or interleaved closed-loop paths arranged proximate the high-power density device to increase local surface area and to promote temperature uniformity. In other implementations, the primary fluid circuit comprises a single flow passage having an increased hydraulic diameter relative to the interleaved-channel implementation, such as a single wider passage extending across a region of the heat spreader adjacent the high-power density device. In further implementations, the primary fluid circuit comprises an array of microchannels or mesoscale channels fluidly coupled by one or more manifolds, such that the electrically conducting fluid is distributed among parallel channels in a region of high heat flux and is recollected downstream for heat exchange with a thermally coupled circuit and/or for continued circulation within the heat spreader.

In some embodiments, the primary fluid circuit comprises a plurality of distinct primary fluid loops that are each fully sealed within the heat spreader and each contain the electrically conducting fluid. In such implementations, each distinct primary fluid loop is hydraulically coupled to a respective pump such that a circulation rate and a flow direction of the electrically conducting fluid can be independently controlled on a per-loop basis. Further, the distinct primary fluid loops may have different geometries, dimensions, and/or orientations within the heat spreader. For example, a first primary fluid loop may be arranged to circulate the electrically conducting fluid in a first direction within a first region of the heat spreader while a second primary fluid loop is arranged to circulate the electrically conducting fluid in a second direction different from the first direction, including a second direction substantially perpendicular to the first direction, to tailor local heat spreading and temperature uniformity.

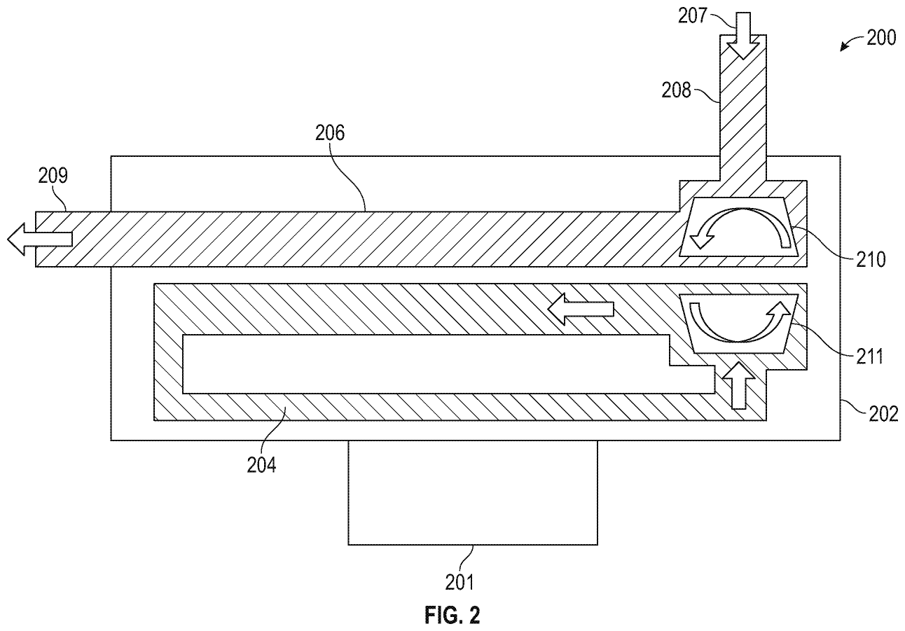

FIG. 2 is a cross-sectional schematic view of a thermal management apparatus 200 configured to remove heat from a high-power density device 201 using thermally coupled, fluidly isolated coolant circuits within a heat spreader 202. The heat spreader 202 is configured to be mounted in thermal communication with the high-power density device 201 such that heat generated by the high-power density device 201 is conducted into the heat spreader 202 during operation.

In the illustrated embodiment, the heat spreader 202 contains a primary fluid circuit 204 and a secondary fluid circuit 206 that are fluidly isolated from one another while being thermally coupled through a heat exchange region 203. The primary fluid circuit 204 is positioned within the heat spreader 202 proximate a region adjacent the high-power density device 201 such that a coolant circulating in the primary fluid circuit 204 absorbs heat from the heat spreader 202 in a vicinity of the high-power density device 201 and transports the absorbed heat along the primary fluid circuit 204. In some embodiments, the coolant in the primary fluid circuit 204 comprises an electrically conducting fluid, such as a liquid metal or liquid metal alloy, selected to provide relatively high thermal conductivity and enhanced heat spreading performance near the high-power density device 201. In certain implementations, the primary fluid circuit 204 is fully sealed within the heat spreader 202 to contain the electrically conducting fluid and reduce risk of leakage or contamination.

The secondary fluid circuit 206 contains a secondary fluid 207 that is different from the electrically conducting fluid of the primary fluid circuit 204. For example, the secondary fluid 207 may be water, a water-glycol mixture, a dielectric coolant, or another non-metallic coolant suitable for circulating through external tubing and/or a remote heat rejection element. The secondary fluid circuit 206 includes a secondary fluid inlet 208 and a secondary fluid outlet 209 to permit the secondary fluid 207 to flow through the heat spreader 202, thereby transporting heat away from the heat spreader 202 for subsequent rejection to an external environment or a remote cooling resource.

Heat exchange between the circuits is provided by the heat exchange region 203 within the heat spreader 202. The heat exchange region 203 may comprise, for example, a thermally conductive wall separating flow passages of the primary fluid circuit 204 and the secondary fluid circuit 206, such that heat carried by the electrically conducting fluid in the primary fluid circuit 204 is transferred across the wall into the secondary fluid 207 in the secondary fluid circuit 206.

FIG. 2 further illustrates an example pumping arrangement configured to circulate fluid in the primary fluid circuit 204 without requiring a mechanical shaft penetration or an electrical feedthrough into the primary fluid circuit 204. In the illustrated embodiment, an internal impeller 211 is disposed within the primary fluid circuit 204 and is configured to impart momentum to the electrically conducting fluid to drive circulation within the primary fluid circuit 204. A driver 210 is disposed in the heat spreader 202 outside the primary fluid circuit 204 and is magnetically coupled to the internal impeller 211 through a sealed wall portion of the heat spreader 202. In the embodiment of FIG. 2, the driver 210 comprises a flow-driven rotor that is hydraulically coupled to the secondary fluid circuit 206 such that flow of the secondary fluid 207 through the secondary fluid circuit 206 rotates the driver 210. Rotation of the driver 210 magnetically rotates the internal impeller 211, and rotation of the internal impeller 211 circulates the electrically conducting fluid in the primary fluid circuit 204 while the primary fluid circuit 204 remains sealed.

In operation, flow of the secondary fluid 207 enters the secondary fluid circuit 206 through the secondary fluid inlet 208, drives rotation of the flow-driven rotor driver 210, and exits through the secondary fluid outlet 209. The induced rotation of the internal impeller 211 circulates the electrically conducting fluid through the primary fluid circuit 204, thereby enhancing local heat absorption and spreading near the high-power density device 201. Heat carried by the electrically conducting fluid is transferred at the heat exchange region 203 into the secondary fluid 207, which then transports the heat away from the heat spreader 202 for rejection. This arrangement enables a compact dual-loop architecture in which a high-conductivity electrically conducting fluid can be used locally in a sealed primary circuit near the heat source while a different coolant is used in a secondary circuit for heat transport and rejection.

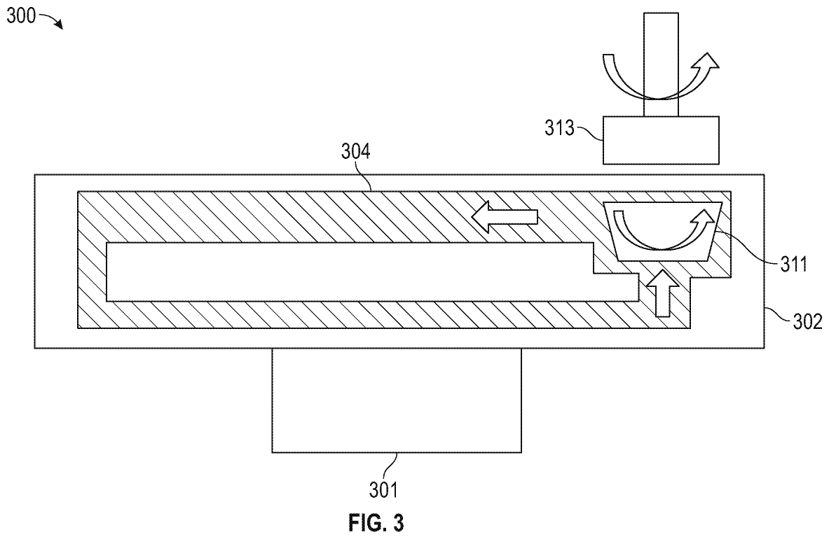

FIG. 3 is a cross-sectional schematic view of a thermal management apparatus 300 configured to remove heat from a high-power density device 301 using an electrically conducting coolant circulating in a primary fluid circuit 304 contained within a heat spreader 302. The heat spreader 302 is configured to be mounted in thermal communication with the high-power density device 301 such that heat generated by the high-power density device 301 is conducted into the heat spreader 302 during operation.

In the illustrated embodiment, the primary fluid circuit 304 is disposed within the heat spreader 302 and is positioned proximate a region adjacent the high-power density device 301. The primary fluid circuit 304 contains an electrically conducting fluid, such as a liquid metal or liquid metal alloy, selected to provide relatively high thermal conductivity to enhance heat absorption and spreading within the heat spreader 302. During operation, the electrically conducting fluid flowing in the primary fluid circuit 304 absorbs heat from a vicinity of the high-power density device 301 and transports the absorbed heat along the primary fluid circuit 304, thereby reducing localized hotspots and improving temperature uniformity across the heat spreader 302.

The primary fluid circuit 304 may be fully sealed within the heat spreader 302 such that the electrically conducting fluid is contained without external plumbing connections and without mechanical shaft penetrations through a wall of the primary fluid circuit 304. In such implementations, the sealed construction can reduce leakage risk and contamination risk associated with electrically conducting fluids, including liquid metals.

To drive circulation of the electrically conducting fluid while maintaining the sealed construction, the thermal management apparatus 300 includes a magnetically coupled pump comprising an internal impeller 311 disposed within the primary fluid circuit 304 and an externally driven driver 313 disposed outside the primary fluid circuit 304. The driver 313 may comprise an electrically driven motor configured to rotate a magnetic drive element adjacent a sealed wall portion of the heat spreader 302. The internal impeller 311 includes magnetic material or permanent magnets arranged to magnetically couple with the magnetic drive element of the driver 313 through the sealed wall. As a result, rotation of the driver 313 causes corresponding rotation of the internal impeller 311 without a mechanical shaft extending into the primary fluid circuit 304 and without an electrical feedthrough into the electrically conducting fluid.

Rotation of the internal impeller 311 imparts momentum to the electrically conducting fluid to circulate the electrically conducting fluid through the primary fluid circuit 304. The circulating electrically conducting fluid thereby functions as an active heat spreading medium within the heat spreader 302, distributing heat away from the region adjacent the high-power density device 301 and enabling more uniform heat transfer from the heat spreader 302 to downstream heat rejection structures and/or thermally coupled cooling circuits, depending on the particular system implementation.

In some embodiments, the driver 313 may be controllable to adjust at least one of rotational speed or rotational direction of the internal impeller 311, thereby modulating flow rate and/or flow direction of the electrically conducting fluid in the primary fluid circuit 304. Such control can enable dynamic thermal management, for example by increasing flow during higher heat load conditions or by reversing flow direction to redistribute temperature gradients within the heat spreader 302.

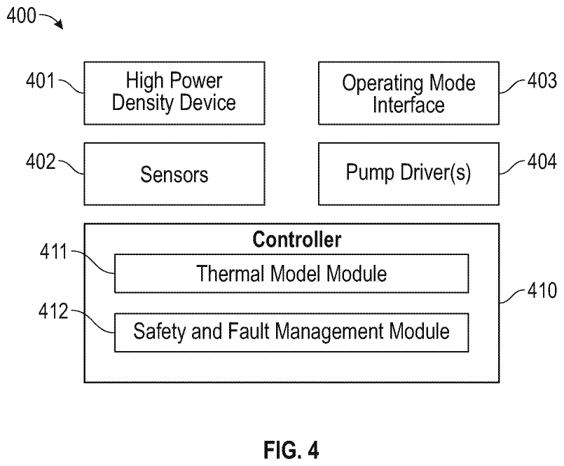

FIG. 4 is a block diagram of an example thermal management control system 400 configured to control operation of a thermal management apparatus for cooling a high-power density device. In the illustrated embodiment, the system 400 includes a high-power density device 401, a set of sensors 402, an operating mode interface 403, one or more pump driver(s) 404, and a controller 410.

The sensors 402 may include one or more temperature sensors positioned to sense temperature at respective locations of at least one of the high-power density device 401 and a heat spreader and/or coolant circuits of the thermal management apparatus. For example, the sensors 402 may include a temperature sensor located on or near a die or package of the high-power density device 401, and one or more additional temperature sensors located at different locations of the heat spreader to sense spatial temperature variation indicative of hotspots and temperature gradients. In some implementations, the sensors 402 may additionally include sensors configured to provide operating condition data, such as flow sensors, pressure sensors, pump speed sensors, current sensors, voltage sensors, or other sensors indicative of thermal management system state.

The operating mode interface 403 is configured to provide one or more signals indicative of an operating mode of the high-power density device 401. In various embodiments, the operating mode may include, for example, a power state, workload level, clock frequency, voltage setting, thermal design power limit, or a throttling state. The operating mode interface 403 may be implemented as a hardware interface, a bus interface, a firmware interface, or a software interface by which the controller 410 receives the operating mode information from the high-power density device 401 or from a host system.

The pump driver(s) 404 are configured to provide drive signals and/or power to one or more pumps of the thermal management apparatus. For example, the pump driver(s) 404 may be configured to control at least one of a speed or a direction of rotation for a magnetically coupled impeller pump, and/or to control energization of a magnetohydrodynamic pump. In embodiments where the thermal management apparatus includes a plurality of pumps respectively coupled to a plurality of flow channels, the pump driver(s) 404 may provide independent drive channels such that each pump can be controlled separately. In certain implementations, the pump driver(s) 404 may include power electronics such as inverters, commutation circuitry, current regulators, voltage regulators, and associated sensing and protection circuitry.

The controller 410 is configured to receive sensor data from the sensors 402 and operating mode information via the operating mode interface 403, and to generate control commands for the pump driver(s) 404 based on at least one of the sensor data or the operating mode information. In some embodiments, the controller 410 is configured to modulate a circulation rate in at least one coolant circuit of the thermal management apparatus in response to a temperature of the high-power density device 401. In some embodiments, the controller 410 is configured to modulate direction of flow in at least one coolant circuit, for example by reversing a pump direction, to redistribute heat within a heat spreader.

In the illustrated embodiment, the controller 410 includes a thermal model module 411 and a safety and fault management module 412. The thermal model module 411 may be configured to estimate thermal conditions of the high-power density device 401 and/or a heat spreader based on the sensor data, including estimating a temperature gradient across at least a portion of the heat spreader. In some implementations, the thermal model module 411 may determine a non-uniform flow command among multiple pumps to reduce a detected or predicted temperature gradient, such as by driving a first pump at a first speed and direction and driving a second pump at a different speed and/or an opposite direction. The safety and fault management module 412 may be configured to detect fault conditions, such as overtemperature, sensor failure, pump stall, abnormal current draw, or loss of commanded flow, and to initiate protective actions, including increasing circulation, limiting pump operation, triggering throttling of the high-power density device 401, or initiating a controlled shutdown.

In some implementations, the controller is configured to coordinate operation of multiple pumps in different modes to adapt cooling performance to changing heat load conditions and spatial heat distributions. For example, during a steady-state operating condition, the controller may command a plurality of pumps to operate in unison at a common speed and common flow direction to provide uniform circulation. During a transient heat load change or a detected hot-spot condition, the controller may command different pumps to operate at different speeds to establish a spatially non-uniform flow distribution that increases local heat removal in a region of elevated temperature. In certain implementations, the controller is configured to reverse a direction of flow in at least one selected channel or loop to redistribute temperature gradients within the heat spreader. The controller may select among such control modes based on temperature sensor data and/or based on an operating mode input indicative of a workload level, a power state, a clock frequency, a throttling state, or another operating condition of the high-power density device.

In some implementations, the controller 410 can selectively command a reversible pump associated with a first channel, loop, or flow path of the primary fluid circuit to operate in a reverse direction relative to a nominal circulation direction so as to oppose or brake fluid motion in the first channel, loop, or flow path, while another pump associated with a second channel, loop, or flow path is driven in a forward direction to increase flow through a second region of the heat spreader. The reversible pump may comprise a magnetohydrodynamic pump, a magnetically coupled impeller pump, or another pump capable of bidirectional operation. Such differential control may be implemented in response to temperature sensor data and/or an operating condition of the high-power density device 401, such as a workload change, a clock-frequency state, a power state, or a localized hot-spot condition, to redistribute coolant toward regions of elevated heat flux and away from regions having lower instantaneous cooling demand.

In some embodiments, the first fluid circuit includes a plurality of magnetohydrodynamic pumps positioned at respective regions of one or more flow channels of the first fluid circuit 104, such that the magnetohydrodynamic pumps operate as electrically controllable flow-regulation elements. For example, the controller 410 may selectively energize a first magnetohydrodynamic pump to increase local flow through a first region of the heat spreader adjacent a portion of the high-power density device exhibiting elevated heat flux, while reducing energization of a second magnetohydrodynamic pump in a second region to decrease local flow through the second region. In some implementations, one or more of the magnetohydrodynamic pumps may be driven in a reverse pumping direction to oppose or brake fluid motion in a selected channel or channel region, thereby redistributing the electrically conducting fluid toward another region of the first fluid circuit. In this manner, the plurality of magnetohydrodynamic pumps may function analogously to a plurality of electrically controlled valves, while also providing active pumping, such that local flow distribution within the heat spreader 102 can be dynamically adjusted based on temperature sensor data, a determined heat map, and/or an operating condition of the high-power density device 401.

Accordingly, FIG. 4 illustrates that the thermal management system 400 can provide closed-loop control of coolant circulation based on temperature sensor data and/or operating mode information, including individualized control of multiple pumps to achieve desired thermal performance and temperature uniformity for the high-power density device 401.

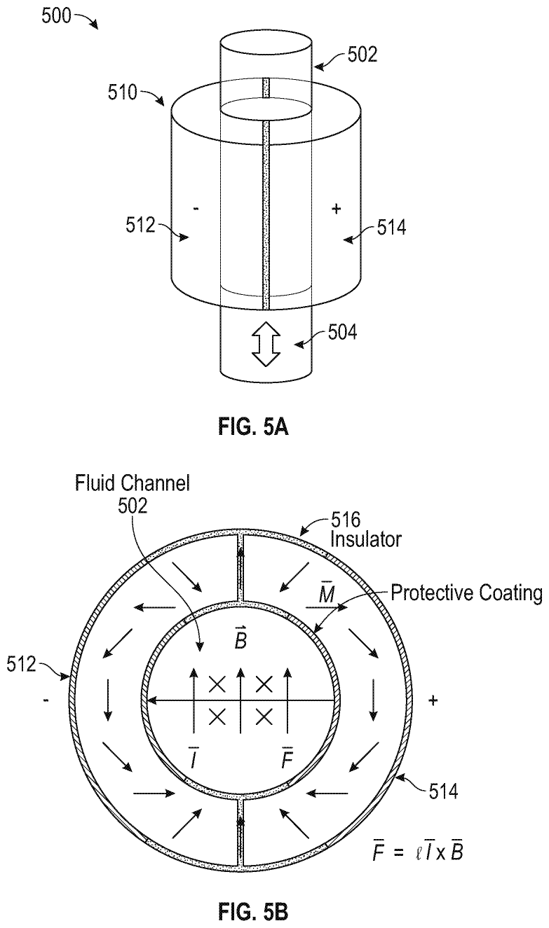

FIGS. 5A and 5B illustrate an example magnetohydrodynamic (MHD) pump 500 configured to generate a pressure rise in an electrically conducting fluid 504 flowing within a conduit 502. In the illustrated embodiment, the conduit 502 comprises a generally cylindrical fluid channel that contains the electrically conducting fluid 504, such as a liquid metal or liquid metal alloy. The MHD pump 500 is configured to impart a net body force on the electrically conducting fluid 504 by establishing an electrical current through the fluid in the presence of a magnetic field, thereby generating a Lorentz force that drives fluid motion along an axis of the conduit 502.

As shown in FIG. 5A, the MHD pump 500 includes a magnetic array 510 positioned about the conduit 502. In some embodiments, the magnetic array 510 comprises a Halbach array arranged to concentrate magnetic flux density within the conduit 502 while reducing stray magnetic fields external to the conduit 502. Reducing stray magnetic fields external to the pump region can be beneficial in packaged electronic systems by reducing magnetic interference with adjacent circuitry, sensors, data storage devices, and other magnetically sensitive components, and by reducing a need for additional magnetic shielding structures. The magnetic array 510 is arranged to produce a magnetic flux density within the conduit 502. In some implementations, the magnetic array 510 comprises a circumferentially arranged set of permanent magnets forming a magnetic structure surrounding the conduit 502, and the magnetic structure may be configured to concentrate magnetic flux within the electrically conducting fluid 504 while reducing stray magnetic fields outside the pump region. In some embodiments, the permanent magnets of the magnetic array 510 comprise neodymium-iron-boron magnets, samarium-cobalt magnets, alnico magnets, or combinations thereof.

The MHD pump 500 further includes a negative electrode 512 and a positive electrode 514 positioned on opposing sides of the conduit 502 in the pump region. The negative electrode 512 and the positive electrode 514 are configured to drive an electrical current through a cross-section of the electrically conducting fluid 504 within the conduit 502. In operation, a voltage applied between the negative electrode 512 and the positive electrode 514 causes current to flow through the electrically conducting fluid 504 in a direction generally transverse to the magnetic field produced by the magnetic array 510. The interaction between the current and the magnetic field produces a Lorentz force within the electrically conducting fluid 504, which results in a pressure rise and corresponding flow of the electrically conducting fluid 504 through the conduit 502. The direction of the generated pumping force can be selected by the polarity of the applied voltage and by the orientation of the magnetic field, and in certain implementations the direction of flow may be reversed by reversing the applied current direction.

In some embodiments, the magnetic array 510 comprises a Halbach arrangement having first and second opposing portions disposed on opposite sides of the conduit 502, wherein the first and second opposing portions are separated from one another by an insulator 516. In certain implementations, the first opposing portion is electrically coupled to function as the negative electrode 512 and the second opposing portion is electrically coupled to function as the positive electrode 514, such that the opposing portions of the Halbach arrangement provide both magnetic-field generation and electrical-current injection for the MHD pump 500. In operation, electrical current passes from one opposing portion to the other through the electrically conducting fluid 504 within the conduit 502 while the Halbach arrangement concentrates magnetic flux density in the pump region, thereby generating a Lorentz force that drives the electrically conducting fluid 504 along the conduit 502. In such implementations, surfaces of the opposing portions exposed to the electrically conducting fluid 504 may include a conductive and corrosion-resistant coating or plating selected to improve electrical contact performance and durability.

FIG. 5B schematically illustrates a cross-sectional view of the pump region of the conduit 502. In the illustrated representation, the magnetic flux density within the conduit 502 is denoted by B, and the electrical current through the electrically conducting fluid is denoted by I. The resulting Lorentz force acting on the electrically conducting fluid is denoted by F, and is expressed by the relationship:

F= [symbol] I ×B

where [symbol] represents an effective length of current conduction within the magnetic field region. The Lorentz force F acts on the electrically conducting fluid to generate a pressure differential along the conduit 502, thereby producing pumping action through the fluid channel.

In the illustrated embodiment of FIG. 5B, an insulator 516 is disposed between electrically conductive portions associated with the negative electrode 512 and the positive electrode 514 to maintain electrical isolation between the electrodes while permitting current flow through the electrically conducting fluid in the conduit 502. In some implementations, surfaces of the electrodes 512, 514 exposed to the environment and/or configured to form current injection interfaces may include protective coatings or plating selected to improve corrosion resistance and electrical contact performance. For example, in certain embodiments, electrode surfaces may be coated with an electroless-nickel electroless-palladium immersion-gold (ENEPIG) plating, and insulating regions may comprise polymeric, ceramic, glass, or oxide materials configured to withstand the operating environment of the electrically conducting fluid.

Accordingly, FIGS. 5A and 5B illustrate an MHD pump architecture in which a magnetic array 510 establishes a magnetic field in a pump region of a conduit 502 while electrodes 512, 514 establish an electrical current through an electrically conducting fluid 504 in the pump region. The resulting Lorentz force generates a pressure rise that drives the electrically conducting fluid 504 through the conduit 502, enabling circulation of a liquid metal coolant within a thermal management system without a mechanically driven impeller and, in some implementations, with reduced moving components in the fluid path.

For the sake of brevity, conventional techniques related to making and using the disclosed embodiments may or may not be described in detail herein. In particular, various aspects of computing systems and specific computer programs to implement the various technical features described herein are well known. Accordingly, in the interest of brevity, many conventional implementation details are only mentioned briefly or are omitted entirely without providing the well-known system and/or process details.

The various components/modules/models of the systems illustrated herein are depicted separately for ease of illustration and explanation. In embodiments of the invention, the functions performed by the various components/modules/models can be distributed differently than shown without departing from the scope of the various embodiments of the invention described herein unless it is specifically stated otherwise.

Aspects of the invention can be embodied as a system, a method, and/or a computer program product at any possible technical detail level of integration. The computer program product may include a computer readable storage medium (or media) having computer readable program instructions thereon for causing a processor to carry out aspects of the present invention.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, element components, and/or groups thereof.

While the present invention has been described with reference to an exemplary embodiment or embodiments, it will be understood by those skilled in the art that various changes may be made and equivalents may be substituted for elements thereof without departing from the scope of the present invention. In addition, many modifications may be made to adapt a particular situation or material to the teachings of the present invention without departing from the essential scope thereof. Therefore, it is intended that the present invention not be limited to the particular embodiment disclosed as the best mode contemplated for carrying out this present invention, but that the present invention will include all embodiments falling within the scope of the claims.

What is claimed is:

1. A thermal management apparatus comprising:
a heat spreader configured to be in thermal communication with a high-power density device;
a primary fluid circuit disposed within the heat spreader and containing an electrically conducting fluid arranged to circulate to absorb and distribute heat from the high-power density device;
a secondary fluid circuit fluidly isolated from and thermally coupled to the primary fluid circuit and containing a fluid different from the electrically conducting fluid; and
a heat rejection element in thermal communication with the secondary fluid circuit,
wherein the secondary fluid circuit is configured to receive heat from the primary fluid circuit and reject the heat at the heat rejection element to effect enhanced heat removal from the high-power density device.

2. The thermal management apparatus of claim 1, further comprising a pump in the primary fluid circuit, the pump being a mechanically driven pump configured to circulate the electrically conducting fluid through the primary fluid circuit.

3. The thermal management apparatus of claim 1, wherein the fluid of the secondary fluid circuit comprises water.

4. The thermal management apparatus of claim 1, wherein the primary fluid circuit is fully sealed within the heat spreader.

5. The thermal management apparatus of claim 1, further comprising a pump in the primary fluid circuit, the pump being a magnetohydrodynamic pump configured to drive circulation of the electrically conducting fluid.

6. The thermal management apparatus of claim 5, wherein the magnetohydrodynamic pump comprises a Halbach array of permanent magnets arranged to concentrate magnetic flux within a section of the primary fluid circuit while reducing stray magnetic fields external to the section.

7. The thermal management apparatus of claim 6, wherein the Halbach array comprises:
a first opposing portion disposed on a first side of the primary fluid circuit and electrically coupled as a negative electrode;
a second opposing portion disposed on a second side of the primary fluid circuit opposite the first side and electrically coupled as a positive electrode; and
an insulator disposed between the first opposing portion and the second opposing portion,
wherein the first opposing portion and the second opposing portion are arranged such that electrical current passes between the negative electrode and the positive electrode through the electrically conducting fluid in the primary fluid circuit.

8. The thermal management apparatus of claim 1, wherein the primary fluid circuit is driven by an impeller magnetically coupled to a driver located in the heat spreader.

9. The thermal management apparatus of claim 8, wherein the driver comprises a flow-driven rotor hydraulically coupled to the secondary fluid circuit such that flow of the fluid in the secondary fluid circuit rotates the driver.

10. The thermal management apparatus of claim 8, wherein the driver comprises an electrically driven motor configured to rotate the driver independently of fluid flow in the secondary fluid circuit.

11. The thermal management apparatus of claim 1, further comprising a controller configured to modulate a circulation rate in at least one of the primary fluid circuit or the secondary fluid circuit in response to a temperature of the high-power density device.

12. The thermal management apparatus of claim 1, wherein the primary fluid circuit comprises a plurality of flow channels disposed in the heat spreader and arranged to circulate the electrically conducting fluid proximate the high-power density device.

13. The thermal management apparatus of claim 12, further comprising a respective pump hydraulically coupled to each of the plurality of flow channels to drive flow of the electrically conducting fluid through the respective flow channel.

14. The thermal management apparatus of claim 13, wherein the respective pumps are individually controllable such that, during operation, a first pump of the respective pumps drives flow in a first direction at a first flow rate in a first flow channel while a second pump of the respective pumps drives flow in a second direction, opposite the first direction, at a second flow rate in a second flow channel.

15. The thermal management apparatus of claim 13, further comprising a control system including a controller and a plurality of temperature sensors positioned to sense temperature at respective locations of at least one of the high-power density device and the heat spreader, wherein the controller is configured to control at least one of speed or direction of at least a subset of the respective pumps based on temperature sensor data from the plurality of temperature sensors.

16. The thermal management apparatus of claim 15, wherein the controller is further configured to control at least one of speed or direction of at least a subset of the respective pumps based on an operating mode of the high-power density device.

17. The thermal management apparatus of claim 16, wherein the operating mode comprises at least one of a power state, a workload level, a clock frequency, a voltage setting, a thermal design power limit, or a throttling state of the high-power density device.

18. The apparatus of claim 15, wherein the controller is configured to determine a temperature gradient across at least a portion of the heat spreader based on the temperature sensor data and to control at least one of speed or direction of the respective pumps to produce a non-uniform flow distribution among the plurality of flow channels that reduces the temperature gradient.

19. A thermal management apparatus comprising:
a heat spreader configured to be mounted in thermal communication with a high-power density device;
a primary fluid circuit fully sealed within the heat spreader and containing a liquid metal arranged to circulate within the heat spreader to absorb heat from a region adjacent the high-power density device;
a secondary fluid circuit fluidly isolated from the primary fluid circuit and containing a non-metallic coolant, the secondary fluid circuit being thermally coupled to the primary fluid circuit through a heat exchange wall within the heat spreader; and
a magnetically coupled pump comprising an internal impeller disposed in the primary fluid circuit and a flow-driven driver disposed in the heat spreader and hydraulically coupled to the secondary fluid circuit,
wherein flow of the non-metallic coolant in the secondary fluid circuit rotates the flow-driven driver, the flow-driven driver magnetically rotates the internal impeller through a sealed wall, and rotation of the internal impeller circulates the liquid metal in the primary fluid circuit while the primary fluid circuit remains fully sealed without a mechanical shaft penetration and without an electrical feedthrough into the primary fluid circuit.

20. A thermal management apparatus comprising:
a heat spreader configured to be mounted in thermal communication with a high-power density device;
a primary fluid circuit fully sealed within the heat spreader and containing a liquid metal arranged to circulate within the heat spreader to absorb heat from a region adjacent the high-power density device;
a secondary fluid circuit fluidly isolated from the primary fluid circuit and containing a non-metallic coolant, the secondary fluid circuit being thermally coupled to the primary fluid circuit through a heat exchange wall within the heat spreader;
a heat rejection element in thermal communication with the secondary fluid circuit; and
a magnetically coupled pump comprising an internal impeller disposed in the primary fluid circuit and an electrically driven motor disposed in the heat spreader, the electrically driven motor being configured to magnetically rotate the internal impeller through a sealed wall,
wherein rotation of the internal impeller circulates the liquid metal in the primary fluid circuit while the primary fluid circuit remains fully sealed without a mechanical shaft penetration and without an electrical feedthrough into the primary fluid circuit.
